(19) United States
(12) Patent Application Publication
(10) Pub. No.: US 2025/0172586 A1
(43) Pub. Date: May 29, 2025

(54) MODULAR TEST SOCKET

(71) Applicant: TSE CO., LTD., Chungcheongnam-do (KR)

(72) Inventors: Hoe Sik Moon, Chungcheongnam-do (KR); Yun Chan Nam, Chungcheongnam-do (KR)

(21) Appl. No.: 18/943,062

(22) Filed: Nov. 11, 2024

(30) Foreign Application Priority Data
Nov. 23, 2023 (KR) 10-2023-0164735

(51) Int. Cl. G01R 1/04

(52) U.S. Cl. CPC G01R 1/0466

(57) ABSTRACT

The present disclosure relates to a modular test socket completed by assembling a plurality of socket modules, in each socket module, an anisotropic electrically-conductive sheet is supported by a frame, and a coupling protrusion part and a coupling aperture part are formed on the frame, whereby the socket modules are coupled to each other in a manner in which the coupling protrusion part of the socket module is assembled to the coupling aperture part of the adjacent socket module, to complete the modular test socket.

### CROSS-REFERENCE TO RELATED APPLICATION

This application claims priority of Korean Patent Application No. 10-2023-0164735, filed on Nov. 23, 2023, in the KIPO (Korean Intellectual Property Office), the disclosure of which is incorporated herein entirely by reference.

### BACKGROUND OF THE INVENTION

### Field of the Invention

The present disclosure relates to a test socket, and more particularly, to a modular test socket which is connected to an electronic component such as a semiconductor package and is used to transmit an electrical signal.

### Description of the Related Art

At present, various types of connectors configured to transmit electrical signals have been employed in various fields such as an electronic industrial field, a semiconductor industrial field, or the like.

Semiconductor devices are manufactured through a pre-process, post-process, and a test process, and among these processes, the test process is a process for testing whether the semiconductor device is operated normally to sort out good products and defective products.

One of the key components applied in the test process is a test socket so-called socket for a test. The test socket is mounted on a printed circuit board electrically connected to a tester for testing an integrated circuit and is utilized to inspect semiconductor devices. The test socket is provided with contact pins, and these contact pins electrically connects terminals (leads) of the semiconductor device to terminals of the printed circuit board. The tester generates an electrical signal for testing the semiconductor device to be connected to the test socket and outputs it to the semiconductor device, and then tests whether the semiconductor device is operated normally using the electrical signal input through the semiconductor device, and the semiconductor device is determined to be a good product or a defective product based on a result of this test.

Typical test sockets include a pogo socket and a rubber socket.

The pogo socket is made by assembling individually manufactured pogo pins into a housing. Recently, the demand for a rubber socket has been increased in a semiconductor test process due to problems such as a damage to a package ball and increased unit price.

The rubber sockets have a structure in which electrically-conductive parts having a plurality of electrically-conductive particles contained inside an elastic material such as silicone are arranged and insulated from each other, inside an insulating part made of an elastic material such as silicone. This rubber socket has the characteristic by which electrical conductivity is exhibited only in a thickness direction, and do not use mechanical means such as soldering or springs, so it has the advantage of having excellent durability and allowing simple electrical connection. In addition, since the rubber socket may absorb a mechanical shock or deformation, it has the advantage of enabling smooth connection with a semiconductor device, etc.

FIG. 1 is a perspective view showing a conventional rubber socket type test socket used in a process for testing a semiconductor device, and FIG. 2 is a cross-sectional view schematically showing a conventional test socket.

A test socket 40 shown in FIGS. 1 and 2 includes an anisotropic electrically-conductive sheet 20 and a frame 30. The anisotropic electrically-conductive sheet 20 consists of a plurality of electrically-conductive parts 22 which come into contact with terminals 11 of a device 10 under test and an insulating part 21 which supports and insulates the plurality of electrically-conductive parts 22 to allow them to be spaced apart from each other. In addition, the frame 30 supports the anisotropic electrically-conductive sheet 20 on a supporting part 31. The electrically-conductive part 22 is comprised of a plurality of electrically-conductive particles contained in an elastic insulating material, and the insulating part 21 is formed of an elastic insulating material.

This test socket 40 is mounted on a tester 50, and when a device 10 under test is pressurized by a pressurizing means (not shown), terminals 11 of the device under test pressurizes upper ends of the elastic electrically-conductive parts 22, so that the electrically-conductive parts 22 become an electrically conducting state in which electricity pass therethrough, and lower ends of the electrically-conductive parts 22 come into contact with a pad 51 of the tester 50, so that the pad 51 of the tester 50 and the terminals 11 of the device 10 under test are electrically connected. As a results, the tester transmits a test signal to the device under test, thereby enabling the device under test to be tested.

In the conventional test socket 40 made of the rubber socket as described above, the frame 30 and the anisotropic electrically-conductive sheet 20 in which one electrically-conductive part 22 and the adjacent electrically-conductive part 22 are structurally connected to each other through the insulating part 21 are integrally manufactured. Therefore, if the electrically-conductive part 22 arranged on a specific area of the test socket is damaged due to high resistance, shock, etc., the entire test socket should be replaced, so manufacturing costs is increased, and the lead time for replacement is increased to reduce the efficiency of the testing process.

In addition, due to tolerance, the terminals 11 of the device 10 under test have a difference in height, and, after manufacturing, the device 10 under test which is relatively wide or has a relatively thin packaging may have a shape in which a central portion is raised upward as compared with an edge portion, or another shape in which it is slightly twisted. FIG. 2 exemplary depicts of a shape in which a central part of the device 10 under test is raised upward.

Therefore, in the test process of the device 10 under test having a height difference of the terminals 11, when the device 10 under test pressurizes the test socket 40 in which the anisotropic electrically-conductive 20 and the frame 30 are formed integrally, the electronically-conductive part 22 that comes into contact with the terminal 11 of the device under test is compressed, but other electronically-conductive parts are not compressed and tries to maintain the previous height or expand. In this way, since the degree of compression is different depending on the heights of the terminals 11, concentrated stress is generated in an upper end of the electrically-conductive part 22 that receives a relatively large pressurizing force, and if this phenomenon is repeated, the electrically-conductive part 22 where the concentrated stress occurs is damaged, resulting in a problem that lifespan of the test socket 40 is shortened.

In addition, when the height difference of the terminals 11 of the device under test device is large, due to the height difference of the terminals 11, it is difficult to control the degree to which the electrically-conductive part 22 is individually compressed. Therefore, as exemplarily shown in (b) of FIG. 2, in “A” section where the terminal 11 and the electrically-conductive part 22 first come into contact with other, the terminal 11 and the electrically-conductive part are in contact with each other, but in “B” section, the terminal 11 and the electrically-conductive part 22 do not in contact with each other, thereby occurring a contact failure.

### SUMMARY OF THE INVENTION

The present disclosure is devised in consideration of the above-described problems, and an object of the present disclosure is to provide a modular test socket that allows partial replacement of test sockets, and is stably operated even with differences in height of terminals of a device under test.

In order to solve the above drawbacks, a modular test socket according to the present disclosure is formed by coupling a plurality of socket modules, each of the socket modules has a rectangular shape and includes an anisotropic electrically-conductive sheet formed in a rectangular shape at one corner portion, and comprising electrically-conductive parts, each of which being comprised of a plurality of electrically-conductive particles contained in an elastic insulating material, and an insulating part supporting and insulating between the electrically-conductive parts; a flat plate shaped frame supporting two adjacent side surfaces of the anisotropic electrically-conductive sheet; a coupling protrusion part formed on the frame at one corner portion adjacent to the anisotropic electrically-conductive sheet and provided with a coupling protrusion; and a coupling aperture part formed by protruding the frame at the other corner portion adjacent to the anisotropic electrically-conductive sheet and having a coupling aperture, wherein the plurality of socket modules are composed of a first socket module, a second socket module, a third socket module, and a fourth socket module arranged in the clockwise direction, and the socket modules are disposed to allow the coupling protrusion part of one socket module to correspond to the coupling aperture part of the adjacent socket module, and the adjacent socket modules are coupled to each other by fitting and assembling the coupling protrusion part on the coupling aperture part such that side surfaces of the anisotropic electrically-conductive sheets come into contact with each other.

A thickness of the insulating part of the at least one socket module may differ from a thickness of the insulating part of another socket module.

A thickness of the electrically-conductive part of the at least one socket module may differ from a thickness of the electrically-conductive part of another socket module.

The first socket module and the third socket module may have the same shaped frame, and the second socket module and the fourth socket module may have the same shaped frame.

A thickness of a portion on which the coupling protrusion part and the coupling aperture part are coupled to each other may be the same as that of the frame.

A tray formed in a rectangular shape and having an edge part arranged at a perimeter may be coupled to a lower sides of the frames to support the frames.

A side surface, which comes into contact with a side surface of the anisotropic electrically-conductive sheet of the adjacent socket module, of the anisotropic electrically-conductive sheet may have a corrugated shape.

In the modular test socket according to the present disclosure, since a plurality of socket modules are assembled to complete one modular test socket, only the damaged socket module may be replaced with new socket module, so it is possible to reduce a manufacturing cost for the test socket, and the test cost of the semiconductor package may be significantly reduced.

In addition, in the modular test socket according to the present disclosure, since a replaceable socket module may be manufactured in advance, the damaged socket module may be quickly replaced with new one, so the manufacturing period for manufacturing new test socket may be shortened, and the efficiency of the test process may be thus increased.

Furthermore, in the modular test socket according to the present disclosure, even in the process for test a device under test having terminals with difference in height, by disposing the socket modules including the electrically-conductive parts with thickness corresponding to height of terminals, it is possible to prevent the electrically-conductive parts from being damaged due to concentrated stress exerted thereto by terminals with a large height, increasing lifetime of the modular test socket, and furthermore it can prevent contact failure caused by the electrically-conductive parts not making proper contact with the terminals with small height, improving an accuracy of the test.

In addition, in the modular test socket according to the present disclosure, by placing the socket modules having the electrically-conductive parts with thickness corresponding to the BGA terminals and the LGA terminal of the hybrid type device under test, it is possible to stably connect the electrically-conductive part of the socket module and the terminals of the hybrid device under test without occurring contact failure, thereby improving the accuracy of the test.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a perspective view showing a conventional test socket;

FIG. 2 is a schematic cross-sectional view showing a test process using a conventional test socket;

FIG. 3 shows a plurality of socket modules according to one embodiment of the present disclosure;

FIG. 4 shows a modular test socket formed by assembling a plurality of socket modules according to one embodiment of the present disclosure;

FIG. 5 shows a modular test socket supported by a tray according to one embodiment of the present disclosure;

FIG. 6 shows an example of a modified shape of side surfaces of the anisotropic electrically-conductive sheets, which come into contact with each other, in the modular test socket according to one embodiment of the present disclosure;

FIG. 7 shows a process of replacing a damaged socket module according to one embodiment of the present disclosure;

FIG. 8 shows a state in which a modular test socket according to one embodiment of the present disclosure is applied to a device under test including terminals having difference in height; and

FIG. 9 shows a state in which a modular test socket according to one embodiment of the present disclosure is applied to a hybrid device under test having both BGA and LGA terminals.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a modular test socket according to the present disclosure will be described in detail with reference to the accompanying drawings.

In the present disclosure, a device under test is placed on an upper side of a test socket, and a tester is placed on a lower side of the test socket, so “upper surface”, “upper side”, “upper end”, and “lower surface”, “lower side”, “lower end” of any component will be described based on this configuration. In addition, the same components as those components previously described are indicated by the same reference numerals, and a description thereof is omitted.

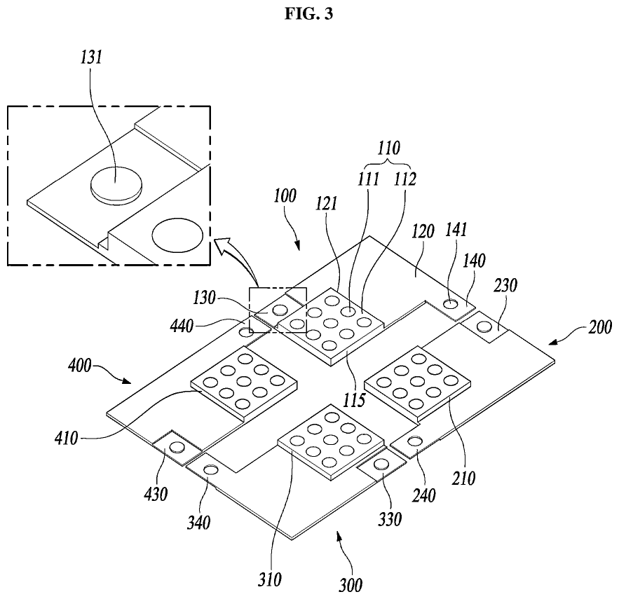

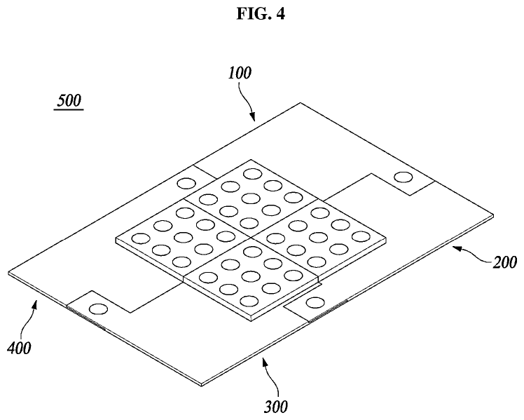

FIG. 3 shows a plurality of socket modules according to one embodiment of the present disclosure, and FIG. 4 shows a modular test socket formed by assembling a plurality of socket modules according to one embodiment of the present disclosure.

As shown in the drawings, a modular test socket 500 according to one embodiment of the present disclosure is formed by coupling a plurality of socket modules to each other, each socket module has a rectangular shape and includes an anisotropic electrically-conductive sheet 110 formed in a rectangular shape at one corner portion; a flat plate shaped frame 120 supporting two adjacent side surfaces of the anisotropic electrically-conductive sheet; a coupling protrusion part 130 formed on the frame at one corner portion adjacent to the anisotropic electrically-conductive sheet and provided with a coupling protrusion 131; and a coupling aperture part 140 formed by protruding the frame at the other corner portion adjacent to the anisotropic electrically-conductive sheet and having a coupling aperture 141. The anisotropic electrically-conductive sheet includes electrically-conductive parts 111, each of which being comprised of a plurality of electrically-conductive particles contained in an elastic insulating material, and an insulating part 112 supporting and insulating between the electrically-conductive parts.

The plurality of socket modules are composed of a first socket module 100, a second socket module 200, a third socket module 300, and a fourth socket module 400 arranged in the clockwise direction, and are characterized in that the socket modules are disposed to allow the coupling protrusion part of one socket module to correspond to the coupling aperture part of the adjacent socket module, and the adjacent socket modules are coupled to each other by fitting and assembling the coupling protrusion part 130 on the coupling aperture part 140 such that side surfaces of the anisotropic electrically-conductive sheets come into contact with each other.

In the above modular test socket 500, an upper side of the electrically-conductive part 111 is connected to a terminal 11 of the device under test and a lower side of the electrically-conductive part 111 is connected to a pad 51 of a tester to transmit an electric signal, thereby enabling the device under test to be tested using the tester, or electrically connecting the device under test and various electronic devices for transmit an electric signal.

Hereinafter, the function of the modular test socket 500 according to one embodiment of the present disclosure, which is mounted on a tester and transmits an electrical signal between the tester and a device under test, is described as an example.

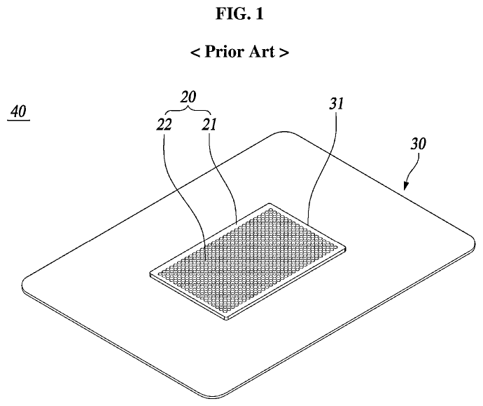

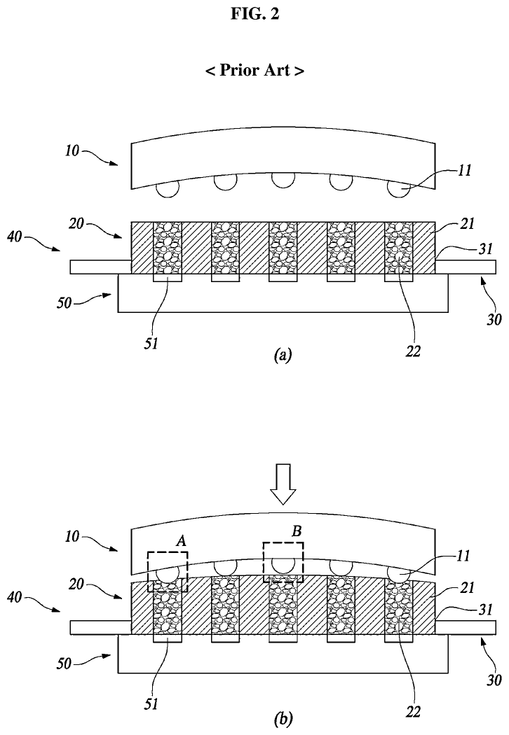

The plurality of socket modules include the first socket module 100, the second socket module 200, the third socket module 300, and the fourth socket module 400 arranged in the clockwise direction, and when the first socket module 100, the second socket module 200, the third socket module 300, and the fourth socket module 400 are assembled, one test socket as shown in FIG. 1 is completed.

Each socket module is formed in an approximately square shape, and although the shapes of the socket modules may differ slightly from each other depending on placement locations, since the socket modules have the same components, the following description will be given using only the first socket module 100.

The first socket module 100 includes the anisotropic electrically-conductive sheet 110 and the frame supporting the anisotropic electrically-conductive sheet.

The anisotropic electrically-conductive sheet 110 is formed in a square shape at one corner of the socket module, and includes the electrically-conductive parts 111, each of which consisting of a plurality of electrically-conductive particles contained in an elastic insulating material, and the insulating part 112 supporting and insulating between the electrically-conductive parts.

The electrically-conductive part 111 may be formed in a form in which the plurality of electrically-conductive particles are aligned in the vertical of the electrically-conductive part, i.e., in the thickness direction, within the elastic insulating material so that an upper end may be connected to the terminal 11 of the test device 10 and a lower end may be connected to the pad 51 of the tester 50. The plurality of electrically-conductive parts 111 are formed on locations, respectively, corresponding to the terminals 11 provided at corresponding locations of the device 10 under test.

As an elastic insulating material constituting the electrically-conductive part 111, a heat-resistant polymer material having a crosslinked structure, for example, silicone rubber, polybutadiene rubber, natural rubber, polyisoprene rubber, styrene-butadiene copolymer rubber, acrylonitrile-butadiene copolymer rubber, styrene-butadiene-diene block copolymer rubber, styrene-isoprene block copolymer rubber, urethane rubber, polyester rubber, epichlorohydrin rubber, ethylene-propylene copolymer rubber, ethylene-propylene-Diene copolymer rubber, soft liquid epoxy rubber, and the like may be employed.

In addition, as the electrically-conductive particles constituting the electrically-conductive part 111, particles having magnetism may be employed such that it may be reacted by a magnetic field. For example, as the electrically-conductive particles, particles obtained by plating a surface of core particle, for example, particles of metals exhibiting magnetism, such as iron, nickel, cobalt, etc., or alloy particles thereof, or particles containing these metals, or particles of these metals, with a metal having excellent electrical-conductivity, such as gold, silver, palladium, radium, or the like; particles obtained by plating a surface of core particle, for example, non-magnetic metal particles, inorganic substance particles such as glass beads or the like, and polymer particles, with electrically-conductive magnetic substance such as nickel, cobalt, or the like; or particles obtained by plating core particle with electrically-conductive magnetic substance and a metal having excellent electrical-conductivity may be employed.

The electrically-conductive part 111 may have a configuration that protrudes downward from a lower surface of the insulating part 112 (described later) to enable the electrically-conductive part to be more easily connected to the pad 51 of the tester. In addition, the electrically-conductive part 111 may be configured to have a part that protrudes upward from an upper surface of the insulating part 112 (see reference number 363 in FIG. 9) to enable the electrically-conductive part to be more easily connected to the terminal 11 of the LGA (land grid array) type device under test. Of course, it is also possible to configure the electrically-conductive part 111 to protrude from both the upper and lower surfaces of the insulating part 112.

The insulating part 112 is provided for supporting and insulating between the electrically-conductive parts 111, is formed of an elastic insulating material to form an appearance of the anisotropic electrically-conductive sheet, and plays a role in supporting the electrically-conductive parts 111 when they receive a contact load. The elastic insulating material constituting the insulating part 112 may be the same material as the elastic insulating material forming the electrically-conductive parts 111. The anisotropic electrically-conductive sheet 110 in which the electrically-conductive parts 111 are arranged on the inner side of the insulating part 112 is supported by a support part 121 provided on the frame 120.

In addition, in the at least one socket module, a thickness of the electrically-conductive part (i.e., a length in the vertical direction) may be formed differently from a thickness of the electrically-conductive part of the other socket module. By configuring the socket module as above, when there is a difference in the height of the terminals of the device under test, the electrically-conductive part corresponding to the terminal at a high position is made thicker, and the electrically-conductive part corresponding to the terminal at a low position is made thinner, so it is possible to prevent an excessive compressive force from being applied to some electrically-conductive parts or contact failure from occurring due to a difference in terminal heights in the device under test, thereby ensuring that the electrically-conductive parts and the terminals come into stably contact with each other.

In addition, a thickness of the insulation part in at least one socket module may be formed differently from a thickness of the insulation part in another socket module. For example, in a case where the thickness of the electrically-conductive part should be formed considerably large, if the thickness of the insulating part is left as is, the electrically-conductive part may be excessively protruded from the insulating part, which may reduce the durability of electrically-conductive part; however, if the thickness of the insulating part is increased in proportion to the thickness of the electrically-conductive part, in a state in which the electrically-conductive part having the sufficient thickness is stably formed within the insulating part, a portion of the electrically-conductive part may be protruded, so that it is possible to prevent the durability of the electrically-conductive part from be deteriorated.

The frame 120 supports the anisotropic electrically-conductive sheet 110 and performs the function of aligning the modular test socket to the tester when the modular test socket is mounted on the tester. The frame 120 is formed in a flat plate shape and supports two adjacent sides of the anisotropic electrically-conductive sheet 110.

The frame 120 may be made of an inelastic insulating material or a metal material. As the inelastic insulating material, an engineering plastic such as polyimide, or various other inelastic insulating materials may be employed, and as a metal material, materials such as aluminum, SUS, iron, and nickel may be employed.

The frame 120 is provided with the coupling protrusion part 130 and the coupling aperture part 140 for assembling the socket module with another socket modules.

The coupling protrusion part 130 is formed on the frame 120 at a corner portion adjacent to the corner portion on which the anisotropic electrically-conductive sheet 110 is supported. The coupling protrusion part 130 is formed to have a configuration in which the coupling protrusion 131 is protruded from the thinned frame 120 whose upper surface is cut to a certain thickness. The coupling protrusion part 130 may be formed by using a method in which a portion of the frame 120, except for the portion where the coupling protrusion 131 is to be formed, is cut using a cutting means such as a laser. Therefore, an entire thickness of the coupling protrusion part 130 (i.e., the thickness from a lower surface of the frame to an upper surface of the coupling protrusion) is the same as the thickness of the frame 120.

The coupling aperture part 140 is formed by protruding the frame 120 at another corner portion adjacent to one corner portion where the anisotropic electrically-conductive sheet 110 is supported. The coupling aperture part 140 is formed to have a configuration in which the coupling aperture 141 penetrates a protruded portion of the thinned frame 120 whose lower surface is cut to a certain thickness. The coupling aperture part 140 may be formed by using a method in which the lower surface of the frame 120 is cut using a cutting means such as a laser, or the like and the coupling aperture 141 is then formed to penetrate the frame. The coupling protrusion 131 and the coupling aperture 141 are formed on positions of the adjacent socket modules corresponding to each other so that the coupling protrusion 131 is accurately inserted into the coupling aperture 141 when the coupling protrusion part 130 and the coupling aperture part 140 are coupled.

The thickness of the frame portion left in the coupling aperture part 140 is the same as the thickness of the frame portion cut off from the coupling protrusion part 130, and the coupling protrusion part 130 and the coupling aperture part 140 are formed to have corresponding sizes, so when the coupling protrusion part 130 is coupled to the coupling aperture part 140, the coupling protrusion part 130 is accurately fitted on the coupling aperture part 140 and the portion at which the coupling aperture part 140 and the coupling protrusion part 130 are coupled to each other has the same thickness as that of the frame 120.

Although the second socket module 200 has the same components as those of the first socket module 100, as compared with the first socket module 100, the second socket module 200 is different in that an anisotropic electrically-conductive sheet 210 is formed on a portion adjacent to the anisotropic electrically-conductive sheet 110 of the first socket module 100, a coupling protrusion part 230 is formed on a portion adjacent to the coupling aperture part 140 of the first socket module 100 and a coupling aperture part 240 is formed at a portion adjacent to the third socket module 300.

The third socket module 300 has the same components as those of the first socket module 100, and the frames of the third and first socket modules may have the same shape.

In addition, the fourth socket module 400 has the same components as those of the second socket module 200, and the frames of the second socket module 200 and the fourth socket module 400 may have the same shape.

As shown in FIG. 3 and FIG. 4, the adjacent socket modules are coupled to each other by, in a state where sides of the anisotropic electrically-conductive sheets are in contact with each other, fitting the coupling protrusion part of one socket module on the coupling aperture part of another socket module to be assembled.

For example, in a state where sides 115, which are not coupled to the frame, of the anisotropic electrically-conductive sheets of the adjacent socket modules are placed to come into contact with each other,
by assembling the coupling protrusion part 230 of the second socket module 200 to the coupling aperture part 140 of the first socket module 100, assembling a coupling protrusion part 330 of the third socket module 300 to the coupling aperture part 240 of the second socket module 200, assembling a coupling protrusion part 430 of the fourth socket module 400 to a coupling aperture part 340 of the third socket module 200, and assembling the coupling protrusion part 130 of the first socket module 100 to a coupling aperture part 440 of the fourth socket module 400, the socket modules may be coupled to each other to complete one modular test socket. It is obvious to those skilled in the art that the assembly sequence is not limited to that described above.

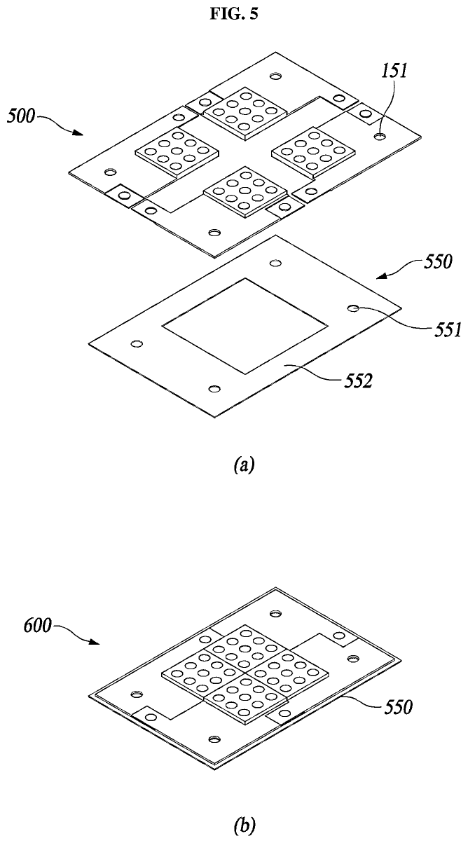

FIG. 5 illustrates a modular test socket 600 supported on a tray according to one embodiment of the present disclosure. Here, (a) of FIG. 5 illustrates a state before the socket modules and the tray are assembled, and (b) of FIG. 5 illustrates a state in which the socket modules and the tray are assembled to form a complete modular test socket.

As shown in the drawing, a tray 550 is formed in a rectangular shape and has an edge part 552 arranged at a perimeter. The edge part 552 of the tray 550 is coupled to lower sides of the frames of the socket modules to perform the function of fixing and supporting the shapes of the frames. The tray 550 may be formed of an inelastic insulating material or a metal material, and may be formed of the same material as the frame.

The modular test socket 600 to which the tray is coupled is formed by placing and coupling the tray 550 on and to a lower side of the modular test socket 500 described above. The modular test socket 500 and the tray 550 may be coupled to each other as follows. A frame coupling hole 151 is formed in the frame of each socket module, and a tray coupling hole 551 is formed in a position, corresponding to the frame coupling hole, of the tray 550, and the frame and tray are coupled to each other via the above coupling holes and screws, or the like. In addition to the above, various coupling method may be utilized.

In this modular test socket 600, by additionally employing the tray 550, it is possible to support the assembled frames more firmly, so that the modular test socket may be used without being disassembled, thereby further enhancing the durability of the modular test socket.

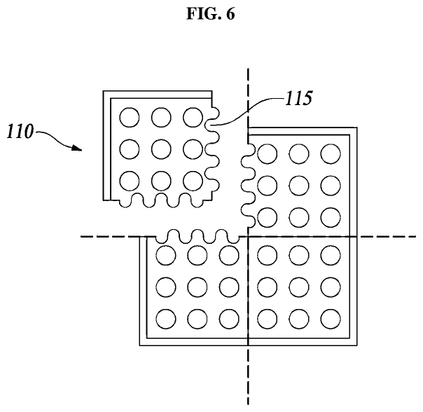

FIG. 6 shows an example of a modified shape of side surfaces of the anisotropic electrically-conductive sheets, which come into contact with each other, in the modular test socket according to one embodiment of the present disclosure.

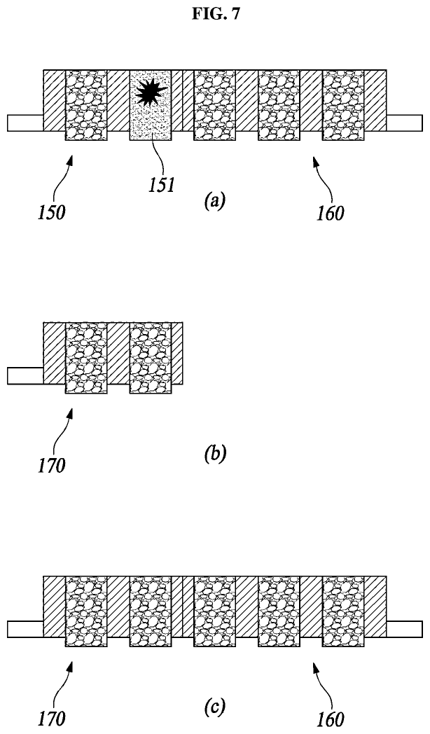

Although the anisotropic electrically-conductive sheet disposed in each modular test socket 500 described above is illustrated as having a flat side surface 115 coming into contact with a side surface of the anisotropic electrically-conductive sheet of the adjacent modular test socket, as shown in FIG. 7, a side surface, which comes into contact with a side surface of the anisotropic electrically-conductive sheet of the adjacent socket module, of the anisotropic electrically-conductive sheet may have corrugated shape to enable the anisotropic electrically-conductive sheets to be firmly coupled to each other. Of course, it is also possible to form the anisotropic electrically-conductive sheets in various other shapes, such as a sawtooth shape, if they may be firmly coupled to each other.

The modular test socket according to one embodiment of the present disclosure may be usefully applied in various situations. Below, for convenience of explanation, the modular test socket is described with reference to only the cross-sectional view thereof, so it should be noted that only some socket modules are depicted.

FIG. 7 illustrates a process for replacing the damaged socket module according to one embodiment of the present disclosure. During the process of using the modular test socket, if some electrically-conductive parts are damaged, i.e., subjected to concentrated stress and the resistance thereof is increased, only the socket module including the damaged electrically-conductive part may be replaced with new one.

As shown in the drawing, for example, in the modular test socket fabricated by assembling a socket module 150 and a socket module 160, if some electrically-conductive part 151 provided in the socket module 150 is damaged, instead of replacing all the socket modules as in the conventional test socket, only the socket module 150 including the damaged electrically-conductive part is separated and removed, and new socket module 170 that has already been manufactured is mounted on a region from which the damaged socket module was removed, thereby enabling a test to be performed using the modular test socket including new socket module 170 and an existing socket module 160.

Therefore, since the modular test socket according to one embodiment of the present disclosure may be used by replacing only the damaged socket module with new socket module, it is possible to reduce a manufacturing cost for the test socket, and the test cost of the semiconductor package may be significantly reduced.

In addition, since in the modular test socket according to one embodiment of the present disclosure, a replaceable socket module may be manufactured in advance, the damaged socket module may be quickly replaced with new one, so the manufacturing period for manufacturing new test socket may be shortened, and the efficiency of the test process may be thus increased.

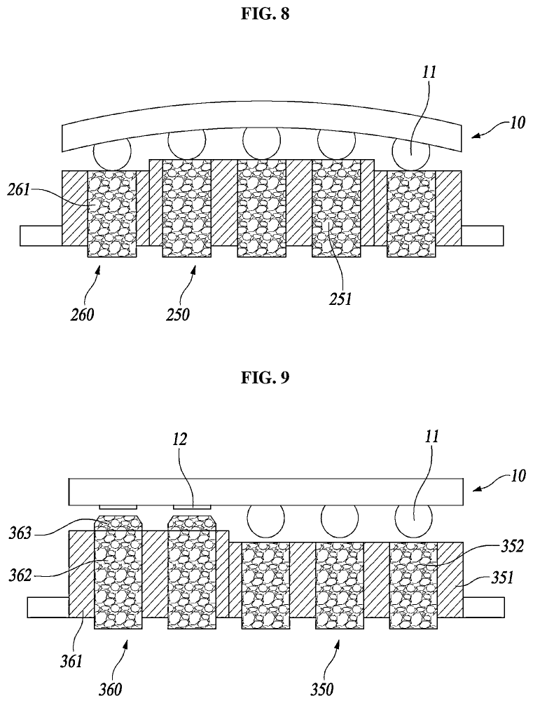

FIG. 8 shows a state in which the modular test socket according to one embodiment of the present disclosure is applied to a device under test including terminals having difference in height.

Due to a tolerance, terminals 11 of a device 10 under test have a difference in height, and after manufacturing, the device 10 under test, which is relatively wide or has relatively thin packaging may have warpage, such as a form in which a central portion is raised upward as compared with an edge, or another form in which it is slightly twisted. The modular test socket of the present disclosure may also be usefully applied to a semiconductor package having warpage.

As shown in the drawing, for example, if the device 10 under test has a warpage caused by a central portion thereof raised upward as compared to an edge, a socket module 250 including electrically-conductive parts 251 with a large thickness is placed on a central portion of the modular test socket and a socket module 260 including electrically-conductive parts 261 with a small thickness is placed on an edge portion, such that it is possible to cope with the height difference of the terminals 11 of the device under test.

Therefore, in the modular test socket according to one embodiment of the present disclosure, even in the process for test a device under test having terminals with difference in height, by disposing the socket modules including the electrically-conductive parts with thickness corresponding to height of terminals, it is possible to prevent the electrically-conductive parts from being damaged due to concentrated stress exerted thereto by terminals with a large height, increasing lifetime of the modular test socket, and furthermore it can prevent contact failure caused by the electrically-conductive parts not making proper contact with the terminals with small height, improving an accuracy of the test

FIG. 9 shows a state in which the modular test socket according to one embodiment of the present disclosure is applied to a hybrid device under test having both BGA and LGA terminals.

Among semiconductor packages, there are hybrid semiconductor packages that have both BGA (ball grid array) terminals and LGA (land grid array) terminals. In these semiconductor packages (devices under test), the BGA terminals are protruded, but the LGA terminals are pad-shaped, so there is a difference in height between the terminals. Therefore, in the test process for the semiconductor package, the BGA terminals are stably connected to the electrically-conductive parts of the test socket, but the LGA terminals may have problem in that they are not properly connected to the electrically-conductive parts.

In the modular test socket according to one embodiment of the present disclosure for a hybrid type device under test having both BGA terminals 11 and LGA terminals 12, as exemplarily shown in the drawing, a regular socket module 350 is placed on a region corresponding to the BGA terminals and a socket module 360 having electrically-conductive parts 362 with a large thickness is placed on a region corresponding to the LGA terminals. By applying the modular test socket including the above-described socket modules 350 and 360, it is possible to easily cope with difference in the shape of the terminals of the device under test.

That is, the socket module 360 corresponding to the LGA terminals is configured such that a thickness of an insulating part 361 is greater than that of an insulating part 351 of the socket module 350 corresponding to the BGA terminals 11 and as a result, a thickness of the electrically-conductive parts 362 is greater than that of the electrically-conductive parts 352 of the socket module 350 corresponding to the BGA terminals 11. Therefore, the electrically-conductive parts 362 may come into contact with the LGA terminals 12. Furthermore, by additionally forming a portion 363, which protrudes upward from an upper surface of the insulating part 361, on each of the electrically-conductive parts 362, the LGA terminal 12 of the device under test may easily come into contact with the protruding portion 363 of the electrically-conductive part 362, so a connection strength between the electrically-conductive part 362 and the LGA terminal 12 may be further improved.

Therefore, in the modular test socket according to one embodiment of the present disclosure, by placing the socket modules having the electrically-conductive parts with thickness corresponding to the BGA terminals and the LGA terminals of the hybrid type device under test, it is possible to stably connect the electrically-conductive part of the socket module and the terminals of the hybrid device under test without occurring contact failure, thereby improving the accuracy of the test.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims. The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A test socket comprising a plurality of socket modules coupled to each other, characterized in that:
each of the socket modules has a rectangular shape and comprises:
an anisotropic electrically-conductive sheet formed in a rectangular shape at one corner portion, and comprising electrically-conductive parts, each of which being comprised of a plurality of electrically-conductive particles contained in an elastic insulating material, and an insulating part supporting and insulating between the electrically-conductive parts;
a flat plate shaped frame supporting two adjacent side surfaces of the anisotropic electrically-conductive sheet;
a coupling protrusion part formed on the frame at one corner portion adjacent to the anisotropic electrically-conductive sheet and provided with a coupling protrusion; and
a coupling aperture part formed by protruding the frame at the other corner portion adjacent to the anisotropic electrically-conductive sheet and having a coupling aperture,
wherein the plurality of socket modules are composed of a first socket module, a second socket module, a third socket module, and a fourth socket module arranged in the clockwise direction, and the socket modules are disposed to allow the coupling protrusion part of one socket module to correspond to the coupling aperture part of the adjacent socket module,
wherein the adjacent socket modules are coupled to each other by fitting and assembling the coupling protrusion part on the coupling aperture part such that side surfaces of the anisotropic electrically-conductive sheets come into contact with each other.

2. The modular test socket of claim 1, wherein a thickness of the insulating part of the at least one socket module differs from a thickness of the insulating part of another socket module.

3. The modular test socket of claim 1, wherein a thickness of the electrically-conductive part of the at least one socket module differs from a thickness of the electrically-conductive part of another socket module.

4. The modular test socket of claim 1, wherein the first socket module and the third socket module have the same shaped frame, and the second socket module and the fourth socket module have the same shaped frame.

5. The modular test socket of claim 1, wherein a thickness of a portion on which the coupling protrusion part and the coupling aperture part are coupled to each other is the same as that of the frame.

6. The modular test socket of claim 1, wherein a tray formed in a rectangular shape and having an edge part arranged at a perimeter is coupled to lower sides of the frames to support the frames.

7. The modular test socket of claim 1, wherein a side surface, which comes into contact with a side surface of the anisotropic electrically-conductive sheet of the adjacent socket module, of the anisotropic electrically-conductive sheet has a corrugated shape.
